(19) United States
(12) Patent Application Publication
(10) Pub. No.: US 2026/0066212 A1
(43) Pub. Date: Mar. 5, 2026

(54) ION IMPLANTATION APPARATUS AND SEMICONDUCTOR DEVICE MANUFACTURING METHOD USING THE SAME

(71) Applicant: Samsung Electronics Co., Ltd., Suwon-si (KR)

(72) Inventors: Haechul Kim, Suwon-si (KR); Myeongshik Shim, Suwon-si (KR); Youngkwon Kim, Suwon-si (KR); Sungseung Lim, Suwon-si (KR); Hongrae Cho, Suwon-si (KR)

(21) Appl. No.: 19/282,460

(22) Filed: Jul. 28, 2025

(30) Foreign Application Priority Data
Aug. 28, 2024 (KR) 10-2024-0116123

(51) Int. Cl. H01J 37/08; C23C 14/48; C23C 28/00; H01J 37/317; H01L 21/3115

(52) U.S. Cl. CPC H01J 37/08; C23C 14/48; C23C 28/00; H01J 37/3171; H01J 2237/31701

(57) ABSTRACT

An ion implantation apparatus includes a source head including an ion source configured to generate ions, a source flange fixing a position of the source head, a source chamber spaced apart from the source head and including a source liner of ground potential, a source bushing disposed between the source flange and the source chamber, and a first insulating film covering at least a portion of an inner surface of the source bushing, the first insulating film being adjacent to the ion source, and the first insulating film including parylene.

### CROSS-REFERENCE TO RELATED APPLICATIONS

This U.S. nonprovisional application is based on and claims priority under 35 U.S.C. § 119 to Korean Patent Application No. 10-2024-0116123, filed on Aug. 28, 2024, in the Korean Intellectual Property Office, the disclosure of which is hereby incorporated by reference herein in its entirety.

### BACKGROUND

The inventive concept relates to an ion implantation apparatus and a semiconductor device manufacturing method using the same.

In order to manufacture semiconductor devices, a process of implanting ions into a substrate is carried out to change the properties of certain areas within the substrate. Such an ion implantation process may include generating and accelerating an ion beam and irradiating the ion beam into the substrate. An ion beam may be generated by applying a high voltage to a source head of the ion implantation apparatus.

### SUMMARY

The inventive concept provides an ion implantation apparatus with an extended usable lifespan and a semiconductor device manufacturing method using the same.

The objective to be solved by the inventive concept is not limited to the objectives above, and other objectives will be clearly understood by those skilled in the art from the description below.

According to an aspect of the inventive concept, there is provided an ion implantation apparatus including a source head including an ion source configured to generate ions, a source flange fixing a position of the source head, a source chamber spaced apart from the source head and including a source liner of ground potential, a source bushing disposed between the source flange and the source chamber, and a first insulating film covering at least a portion of an inner surface of the source bushing, the first insulating film being adjacent to the ion source, and the first insulating film including parylene.

According to another aspect of the inventive concept, there is provided a semiconductor device manufacturing method, the method including preparing an ion implantation apparatus including a source head including an ion source generating ions, a source flange fixing a position of the source head, a source chamber spaced apart from the source head, and a source bushing electrically isolating the source head and the source chamber; forming an insulating film that conformally covers at least a portion of a surface of the source bushing; forming a preliminary material layer on a base to form a substrate including the base and the preliminary material layer; and implanting impurity ions into the preliminary material layer with the ion implantation apparatus, wherein the insulating film includes or is parylene and a thickness of the insulating film is 300 micrometers to 2,000 micrometers.

According to another aspect of the inventive concept, there is provided an ion implantation apparatus including a source head including an ion source configured to generate ions; a source flange fixing the source head; a source chamber spaced apart from the source head, surrounding at least a portion of the ion source, and having a ground potential; a source bushing disposed between the source flange and the source chamber and electrically isolating the source head from the source chamber; an insulating film covering at least a portion of a surface of the source bushing, the insulating film being adjacent to the ion source, and the insulating film including at least one of Parylene C, Parylene N, Parylene D, and Parylene HT; electrodes configured to attract the ions generated from the ion source, and a mass spectrometer configured to extract at least some ions generated from the ion source, based on a charge-to-mass ratio of ions passing through the electrodes.

### BRIEF DESCRIPTION OF THE DRAWINGS

Embodiments will be more clearly understood from the following detailed description taken in conjunction with the accompanying drawings in which:

FIGS. 1A and 1B are diagrams schematically illustrating a configuration of an ion implantation apparatus according to an embodiment;

FIGS. 2A and 2B are cross-sectional views schematically illustrating the arrangement relationship of a source bushing and an insulating film according to an embodiment;

FIG. 3 is a partially enlarged view showing area A of FIG. 2A;

FIG. 4A is a graph showing the degree of water vapor permeability of an insulating film according to an embodiment;

FIG. 4B is a graph showing a dielectric strength of an insulating film according to an embodiment;

FIG. 4C is a graph showing a coefficient of friction of an insulating film according to an embodiment;

FIG. 4D is a graph showing a wear index of an insulating film according to an embodiment;

FIG. 5 is a diagram schematically illustrating a configuration of an ion implantation apparatus according to an embodiment; and

FIGS. 6A, 6B, 6C and 6D are cross-sectional views illustrating a semiconductor device manufacturing method, according to an embodiment.

### DETAILED DESCRIPTION OF THE EMBODIMENTS

Hereinafter, embodiments of the inventive concept will be described more fully with reference to the accompanying drawings. In the drawings, like elements are labeled like reference numerals and repeated description thereof will be omitted. As the inventive concept allows for various changes and many different forms, particular embodiments will be illustrated in the drawings and described in detail in the written description. However, this is not intended to limit the inventive concept to particular modes of practice.

In the embodiments below, while such terms as “first”, “second”, etc., may be used to describe various components, such components should not be limited to the above terms. The above terms are used only to distinguish one component from another.

In the embodiments below, an expression used in the singular form encompasses the expression in the plural form. Thus, the description of a single item that is provided in plural should be understood to be applicable to the remaining plurality of items, unless it has a clearly different meaning in the context.

In the embodiments below, it is to be understood when a component is described as “including” or “having”, etc., a particular element or group of elements, it is to be understood that the component is formed of only the element or the group of elements, or the element or group of elements may be combined with additional elements to form the component, unless the context indicates otherwise.

As used herein the terms “covering”, “on” and “disposed on” are intended to mean that an element is over or on or aside another element. The elements may be touching or not. Also an element need not cover an entire surface of an element to be considered “covering” or “on” or “disposed on” the element. The terms are intended to encompass one element covering or on all or any part of another element, unless it is specified that an element “entirely covers” another element, in which case one element covers all of another element.

As used herein, the term “adjacent” may be used to mean that an element is near another element. The two elements need not be touching or directly contacting one another.

As used herein, the term “and/or” includes any and all combinations of one or more of the associated listed items.

In the drawings, for convenience of description, sizes of components may be exaggerated or contracted. For example, because sizes and thicknesses of components in the drawings are arbitrarily illustrated for convenience of description, the following embodiments are not limited thereto.

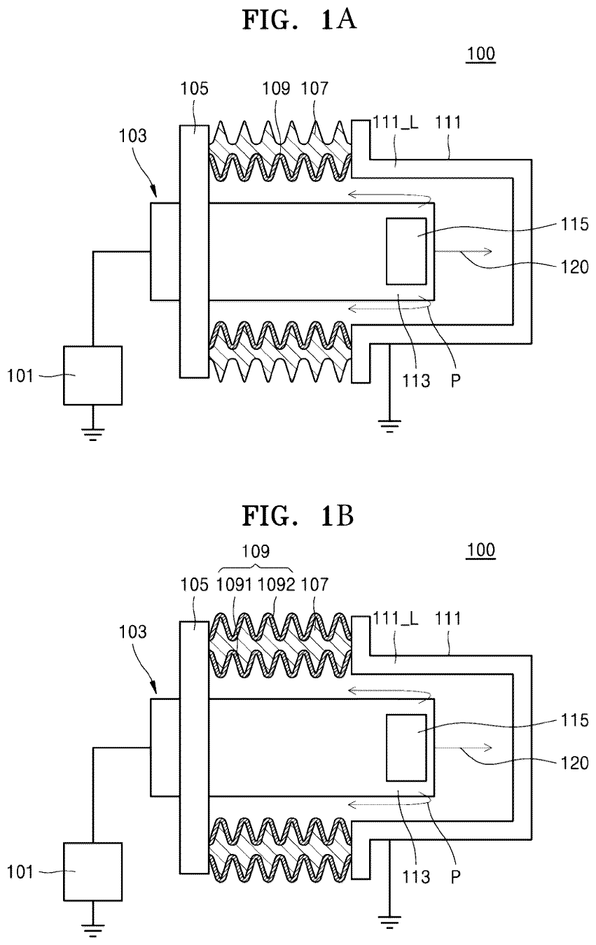

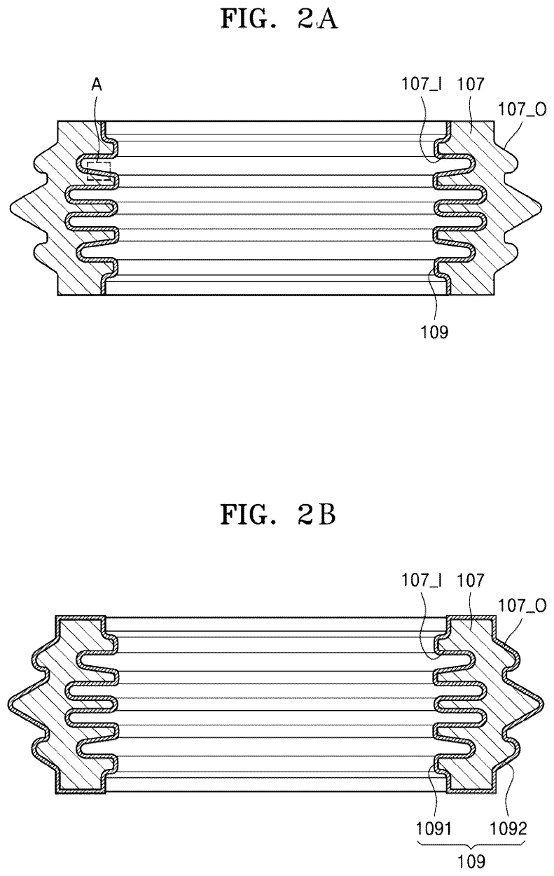

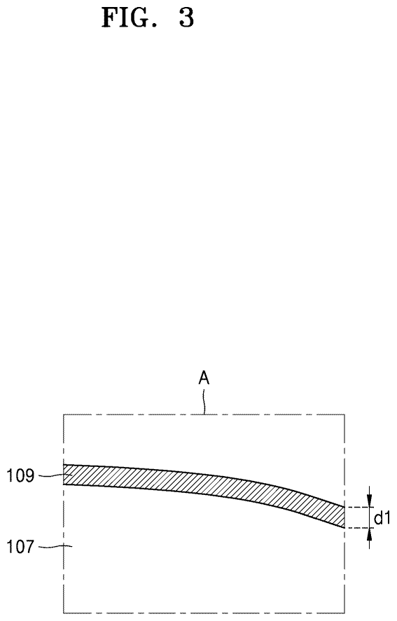

FIGS. 1A and 1B are diagrams schematically illustrating a configuration of an ion implantation apparatus 100 according to an embodiment, and FIGS. 2A and 2B are cross-sectional views schematically illustrating the arrangement relationship of a source bushing 107 and an insulating film 109 according to an embodiment. FIG. 3 is a partially enlarged view showing area A of FIG. 2A.

Referring to FIGS. 1A and 1B, the ion implantation apparatus 100 according to an embodiment may include a power supply unit 101, a source head 103, a source flange 105, the source bushing 107, the insulating film 109, and a source chamber 111.

The source head 103 may include an ion source 113 configured to generate ions. The ion source 113 is a device that generates ions and may include an arc chamber 115 in which ionization occurs. The ion source 113 may generate an ion beam 120 by using a dopant gas and a filament. In an embodiment, the ion source 113 may include an indirectly heated cathode (IHC) housed within a tungsten chamber. The dopant gas may be supplied to the ion source 113 through a supply gas source communicating with the source head 103. The dopant gas may be any suitable gas. For example, the dopant gas may be at least one of a fluorine-containing gas such as boron trifluoride (BF₃), germanium tetrafluoride (GeF₄), silicon tetrafluoride (SiF₄), or hydrogen (H₂), phosphine (PH₃), and/or arsine (AsH₃) gases.

In an embodiment, the power supply 101 may apply a high voltage to the source head 103 to extract and accelerate only positive ions among the ions generated within the arc chamber 115 of the source head 103. The power supply unit 101 may apply a high voltage of 40 kV to 80 kV, or 35 kV to 75 kV, to the source head 103.

The source chamber 111 may include a source liner 111_L. The source liner 111_L may be inserted into an inner wall of the source chamber 111 to be fixed thereto. The source liner 111_L may prevent contamination of the inner wall of the source chamber 111. The source liner 111_L may have ground potential. The source flange 105 may be configured to secure the source head 103. The source head 103 may be inserted parallel to and fixed inside the source flange 105. The source flange 105 may be in contact with the source head 103.

The source bushing 107 may be arranged between the source flange 105 and the source chamber 111. A first surface of the source bushing 107 may be in contact with the source liner 111_L, and a second surface of the source bushing 107 may be in contact with the source flange 105. The source bushing 107 may electrically isolate the source head 103 including the ion source 113, from the source chamber 111. For example, the source bushing 107 may be an insulator between the source chamber 111 including the source liner 111_L having ground potential and the source head 103 receiving a high voltage from the power supply unit 101. The source bushing 107 may include materials such as aluminum oxide (Al₂O₃), calcium carbonate (Ca₂CO₃), polytetrafluoroethylene (PTFE), and/or epoxy resin.

As described above, in various embodiments, the ion implantation apparatus 100 may use a fluorine-containing gas such as boron trifluoride (BF₃), germanium tetrafluoride (GeF₄), and silicon tetrafluoride (SiF₄) as a dopant gas to generate ions, and the material of the source head 103, such as the arc chamber 115, may include or be tungsten (W). During an ion generation process of the ion implantation apparatus 100, the dopant gas may unintentionally leak in a direction P toward the source bushing 107, and the source bushing 107 may be exposed to contaminants such as tungsten hexafluoride (WF₆) generated by the reaction of the dopant gas containing fluorine (F) and the tungsten (W) material of the surrounding components (3F₂+W→WF₆).

A conductive film (e.g., a tungsten film) is deposited on a surface of the source bushing 107 exposed to the dopant gas for a long period of time, which may cause arcing to occur in the source bushing 107, thereby damaging the ion implantation apparatus 100. For example, if high-voltage arcing occurs toward the source liner 111_L of the ground potential from the source flange 105 to which high voltage is applied, cracks may occur on an inner surface of the source bushing 107 or damage may occur to peripheral devices.

The ion implantation apparatus 100 according to various embodiments may include the insulating film 109 including parylene and covering at least a portion of a surface of the source bushing 107. Parylene may be a general term for several types of para-xylylene polymers. For example, the parylene included in the insulating film 109 may include at least one of Parylene C, Parylene N, Parylene D, and/or Parylene HT. FIGS. 1A and 2A illustrate the insulating film 109 disposed on an inner surface 107_I of a source bushing 107, and FIGS. 1B and 2B illustrate the insulating film 109 including a first insulating film 1091 disposed on the inner surface 107_I of the source bushing 107 and a second insulating film 1092 disposed on an outer surface 107_O of the source bushing 107. In an embodiment, the insulating film 109 may cover an upper surface and a lower surface of the source bushing 107 as illustrated in FIG. 2B, and the first insulating film 1091. The second insulating film 1092 may be continuously connected to each other. The first insulating film 1091 and the second insulating film 1092 may be formed of a same material. Referring to FIGS. 1A and 1B, the insulating film 109 may be in contact with the source flange 105 and the source chamber 111.

Referring to FIGS. 2A, 2B, and 3, the source bushing 107 includes the inner surface 107_I and the outer surface 107_O, which are curved, and the insulating film 109 may conformally cover at least a portion of the surface of the source bushing 107. The term “curved” may include one or more bends. The insulating film 109 may be conformally deposited on the surface of the source bushing 107 by using chemical vapor deposition (CVD). The insulating film 109 conformally covers the surface of the source bushing 107 and has a curvature substantially the same as that of the surface of the source bushing 107, thereby extending a deposition path of a contaminant (e.g., WF₆) by a dopant gas. For example, the insulating film 109 may extend a path for a contamination source to reach the surface of the source bushing 107 and/or the insulating film 109 to thereby prevent and reduce redeposition of the contamination source in the form of a polymer on the source bushing 107 and/or the insulating film 109.

The insulating film 109 may have an appropriate thickness that maintains insulating properties even under high voltage applied from the power supply unit 101. In an embodiment, a thickness (d1, FIG. 3) of the insulating film 109 may be 300 micrometers to 2,000 micrometers, or 500 micrometers to 1,800 micrometers, or 700 micrometers to 1,600 micrometers. In an embodiment, a breakdown voltage of the insulating film 109 may be greater than or equal to 40 kV, or 40 kV to 80 kV.

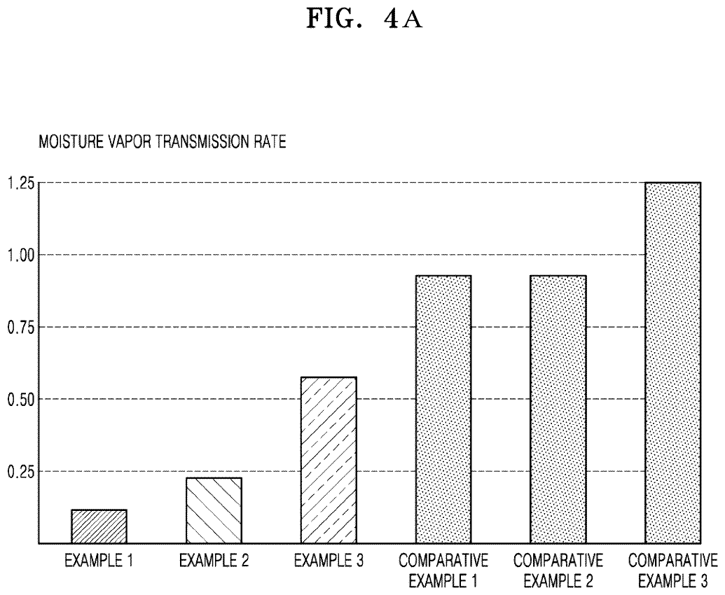

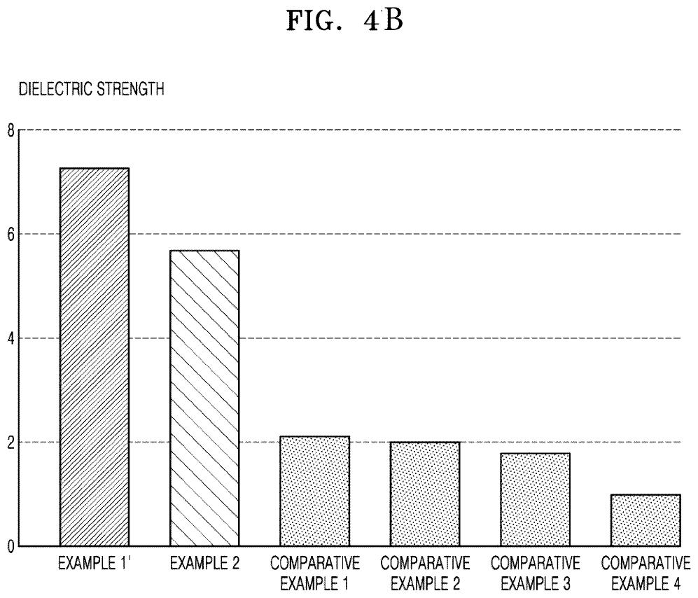

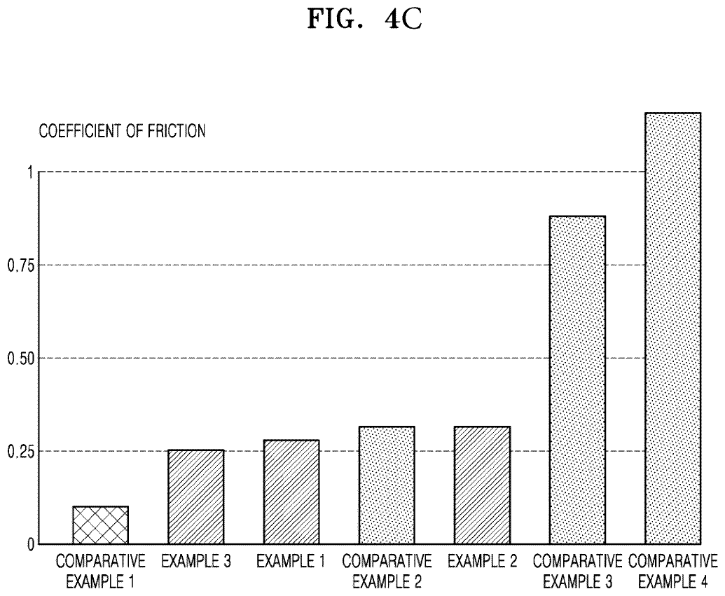

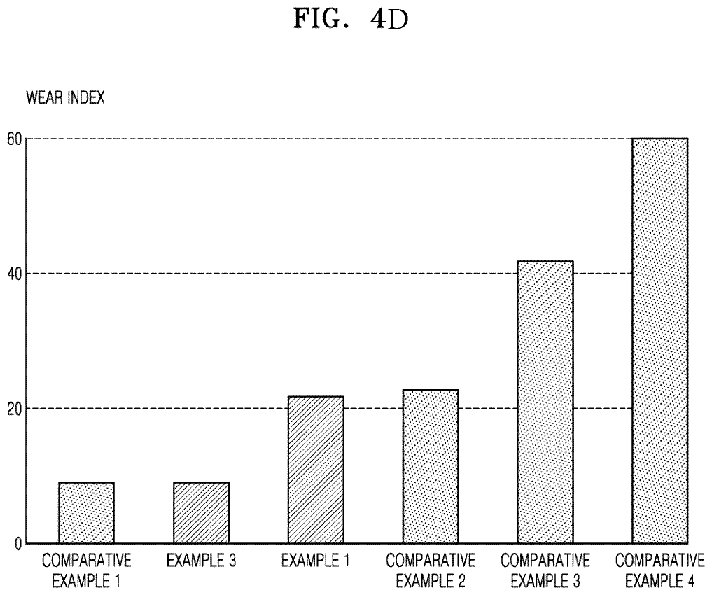

FIGS. 4A, 4B, 4C, and 4D are graphs showing a moisture vapor transmission rate, dielectric strength, coefficient of friction, and wear index of the insulating film according to an embodiment (109, see FIG. 1A), respectively.

Example 1, Example 2, Example 3, Comparative Example 1, Comparative Example 2, and Comparative Example 3 illustrated in FIG. 4A represent cases where the insulating film (109, see FIG. 1A) includes Parylene C, Parylene F, Parylene N, urethanes, epoxies, and polyvinyl chloride (PVC), respectively. Referring to FIG. 4A, under the conditions of 1 mil film, 90 % RH, 100° F. (38° C.), moisture vapor transmission rates of Comparative Example 1 (urethane), Comparative Example 2 (epoxy), and Comparative Example 3 (PVC) are 0.9, 0.9, and 1.25 g/100 in²/24 Hr, respectively, while Example 1 (Parylene C), Example 2 (Parylene F), and Example 3 (Parylene N) may have low moisture vapor transmission rates of about 0.13, 0.24, and 0.6 g/100 in ²/24 Hr, respectively. Through this, the insulating film 109 in the ion implantation apparatus (100, see FIG. 1A) according to various embodiments may act as an effective moisture and chemical barrier layer protecting a component (e.g., the source bushing (107, see FIG. 1A)) that faces a harsh chemical environment.

In an embodiment, the volume resistivity of the insulating film (109, see FIG. 1A) may be greater than or equal to 10¹⁶ Ω cm and less than or equal to 10¹⁷ Ω cm, for example, about 8.8×10¹⁶ Ω cm. In an embodiment, the surface resistance of the insulating film (109, see FIG. 1A) may be about 10¹⁴ Ω. In an embodiment, the dielectric strength of the insulating film (109, see FIG. 1A) may be greater than or equal to 4 kV/mil. A dielectric strength of the insulating film may be. less than or equal to 20 kV/mil. A dielectric strength may be 5 kV/mil to 20 kV/mil, or 5 kV/mil to 19 kV/mil, or 5 kV or more.

Example 1′, Example 2, Comparative Example 1, Comparative Example 2, Comparative Example 3, and Comparative Example 4 illustrated in FIG. 4B represent cases where the insulating film (109, see FIG. 1A) includes Parylene N&F, Parylene C, silicone, polyurethane, epoxies, and acrylic resins, respectively. Referring to FIG. 4B, the dielectric strengths of Comparative Example 1 (silicone), Comparative Example 2 (polyurethane), Comparative Example 3 (epoxy), and Comparative Example 4 (acrylic resin) are about 2.1, 2, 1.8, and 1 kV/mil, respectively, while Example 1′ (Parylene N&F) and Example 2 (Parylene C) may have high dielectric strengths of about 7.2 kV/mil and 5.8 kV/mil, respectively. In the ion implantation apparatus according to various embodiments (100, see FIG. 1A), the insulating film (109, see FIG. 1A) has a high dielectric strength and a high surface resistance and volume resistivity that remain constant even when temperature changes, and thus a barrier layer with excellent electrical insulation properties may be formed.

Comparative Example 1, Example 3, Example 1, Comparative Example 2, Example 2, Comparative Example 3, and Comparative Example 4 illustrated in FIG. 4C represent cases where the insulating film (109, see FIG. 1A) includes PTFE, Parylene N, Parylene C, polyurethane, Parylene F, glass, and silicon rubber, respectively. Referring to FIG. 4C, coefficients of friction of Comparative Example 1 (PTFE), Comparative Example 2 (polyurethane), Comparative Example 3 (glass), and Comparative Example 4 (silicon rubber) are about 0.1, 0.28, 0.85, and 1.2, respectively. The coefficients of friction of Example 3 (Parylene N), Example 1 (Parylene C), and Example 2 (Parylene F) are 0.25, 0.26, and 0.28, respectively, which may be significantly lower than those of Comparative Example 3 (glass) and Comparative Example 4 (silicon rubber). Through this, using the ion implantation apparatus (100, see FIG. 1A) according to various embodiments, the insulating film (109, see FIG. 1A) deposition of a contaminant on the insulating film (109, see FIG. 1A) by a dopant gas or the like may be reduced.

Comparative Example 1, Example 3, Example 1, Comparative Example 2, Comparative Example 3, and Comparative Example 4 illustrated in FIG. 4D represent cases where the insulating film (109, see FIG. 1A) includes PTFE, Parylene N, Parylene C, high impact PVC (HIPVC), epoxy, and urethane, respectively. Referring to FIG. 4D, wear indices of Comparative Example 1 (PTFE), Comparative Example 2 (HIPVC), Comparative Example 3 (epoxy), and Comparative Example 4 (urethane) are about 9, 22, 42, and 60, respectively. The wear indices of Example 3 (Parylene N) and Example 1 (Parylene C) are about 9 and 21, respectively, which may be significantly lower than those of Comparative Example 3 (epoxy) and Comparative Example 4 (urethane). As described above, in the ion implantation apparatus (100, see FIG. 1A) according to various embodiments, the insulating film (109, see FIG. 1A) has excellent chemical resistance as well as excellent wear resistance, thereby extending the usable lifespan of the ion implantation apparatus (100, see FIG. 1A).

Referring to Comparative Example 1 (PTFE) of FIG. 4C and Comparative Example 1 (PTFE) of FIG. 4d, Comparative Example 1 (PTFE) has a low coefficient of friction and a low wear index, but because PTFE is difficult to apply a CVD process thereto due to its material properties and must be formed by spraying, it may be difficult to secure a coating layer with a uniform thickness. In contrast, in the case of an insulating film including parylene, as in various embodiments, uniformity of thickness (step coverage) may be secured using a CVD process. For example, the curved surface of the source bushing (107, see FIG. 1A) may be uniformly covered.

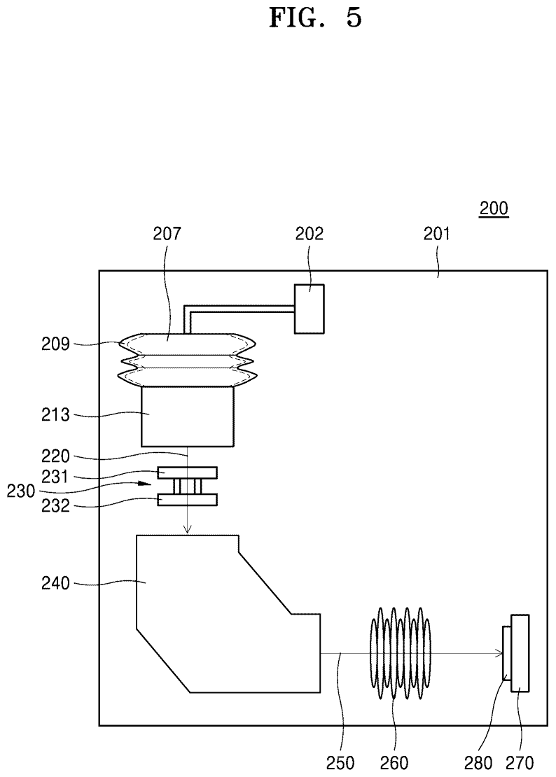

FIG. 5 is a diagram schematically illustrating a configuration of an ion implantation apparatus according to an embodiment.

Referring to FIG. 5, an ion implantation apparatus 200 according to various embodiments may include a housing 201, a supply gas source 202, a source bushing 207, an insulating film 209, an ion source 213, a plurality of electrodes 230, a mass spectrometer 240, an acceleration or deceleration stage 260, and a substrate support 270.

The supply gas source 202 may be connected to the ion source 213. The dopant gas may be supplied from the supply gas source 202 to the ion source 213. For example, in some embodiments, the dopant gas may be at least one of a fluorine-containing gas such as boron trifluoride (BF₃), germanium tetrafluoride (GeF₄), silicon tetrafluoride (SiF₄), or hydrogen (H₂), phosphine (PH₃), and/or arsine (AsH₃) gases.

The ion source 213 may include an IHC housed within a tungsten chamber. The ion source 213 may be included within a larger housing 201. As the ion source 213 is biased to a significant voltage, the ion source 213 may be insulated from ground potential through the source bushing 207.

At least a portion of a surface of the source bushing 207 may be covered with the insulating film 209 including parylene. For example, as illustrated in FIG. 5, an inner surface of the source bushing 207 may be covered with the insulating film 209. Parylene included in the insulating film 209 may collectively refer to various types of para-xylylene polymers, and may include, for example, at least one of Parylene C, Parylene N, Parylene D, and/or Parylene HT. The insulating film 209 of FIG. 5 may correspond to the insulating film 109 described above with reference to FIGS. 1A and 2A.

Referring to FIG. 5, a side surface of the source bushing 207 may be curved. For example, the side surface of the source bushing 207 may be bumpy to maximize the surface area thereof, and the insulating film 209 may conformally cover the surface of the source bushing 207. In an embodiment, the insulating film 209 may be deposited on the surface of the source bushing 207 through a CVD process, and the insulating film 209 may have a curvature substantially the same as that of the surface of the source bushing 207.

The ion implantation apparatus 200 may further include a plurality of electrodes 230. The plurality of electrodes 230 are positioned outside the ion source 213 and may attract ions generated within the ion source 213. The plurality of electrodes 230 may be suitably biased to attract ions generated within the ion source 213. In an embodiment, the plurality of electrodes 230 may include an extraction electrode 231 and a suppression electrode 232. The extraction electrode 231 and the suppression electrode 232 may be electrically separated from each other. Positions of the plurality of electrodes 230 may be adjusted through a manipulation assembly.

An ion beam 220 that is extracted may enter the mass spectrometer 240. The ion beam 220 may flow through a guide tube within the mass spectrometer 240. In an embodiment, a focusing element, such as a quadrupole lens or an einsel lens, may be used to focus the ion beam 220. The mass spectrometer 240 may extract only ions having a desired charge-to-mass ratio by including a resolution aperture located in the output section. An ion beam 250 extracted from the mass spectrometer 240 may be implanted into a substrate 280 that may be mounted on the substrate support 270. In an embodiment, one or more acceleration or deceleration stages 260 may adjust velocity of the ion beam 250.

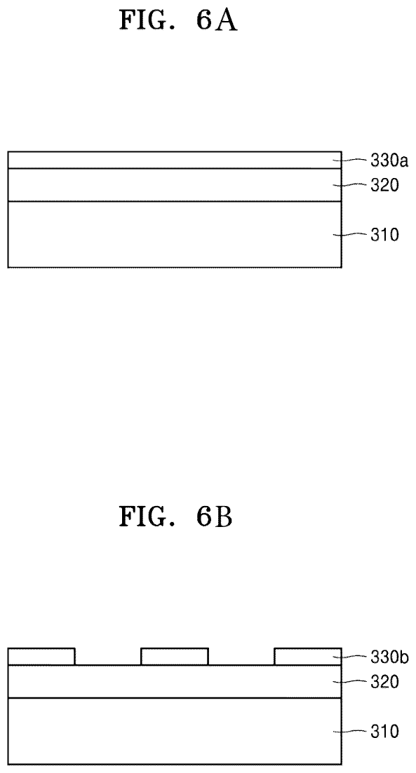

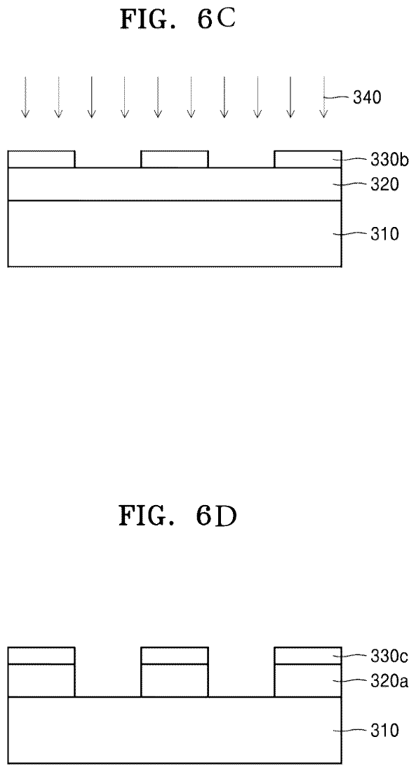

FIGS. 6A to 6C are cross-sectional views illustrating a semiconductor device manufacturing method according to an embodiment.

Referring to FIGS. 6A to 6C together with FIGS. 1A and 1B, the semiconductor device manufacturing method using an ion implantation apparatus, according to an embodiment, may include an operation of preparing an ion implantation apparatus 10 including the source head 103 including the ion source 113 generating ions, the source flange 105 fixing the source head 103, the source chamber 111 spaced apart from the source head 103, and the source bushing 107 electrically isolating the source head 103 from the source chamber 111.

The method may include an operation of forming the insulating film 109 that conformally covers at least a portion of the curved surface of the source bushing 107. The insulating film 109 including parylene may be formed. A thickness of the insulating film 109 may be for example, 300 micrometers to 2,000 micrometers, or 500 micrometers to 1,800 micrometers, or 700 micrometers to 1,600 micrometers. The insulating film 109 may be formed by using CVD. In an embodiment, the insulating film 109 may be formed on the inner surface 107_I of the source bushing 107. In an embodiment, the insulating film 109 may be formed to entirely cover the surface of the source bushing 107. The insulating film 109 may include at least one of Parylene C, Parylene N, Parylene D, and/or Parylene HT. The insulating film 109 may be in contact with the source chamber 111, the source flange 105, and the source bushing 107. A dielectric strength of the insulating film 109 may be 4 kV/mil or more. A dielectric strength of the insulating film may be less than or equal to 20 kV/mil. A dielectric strength may be 5 kV/mil to 20 kV/mil, or 5 kV/mil to 19 kV/mil, or 5 kV or more.

A volume resistivity of the insulating film 109 may be 10¹⁶ Ω·cm or more, or 10¹⁶ Ω cm to 10¹⁷ Ω cm.

The method may include an operation of forming a preliminary material layer (e.g., a preliminary upper material layer 330a) on a base 310 so as to include the base 310 and the preliminary material layer. Thereafter, impurity ions may be implanted into the preliminary material layer by using the ion implantation apparatus 100 including the insulating film 109.

Referring to FIG. 6A, a lower material layer 320 may be formed on the base 310. The preliminary upper material layer 330a may be formed on the lower material layer 320. The base 310 may be a semiconductor substrate.

Referring to FIG. 6B, the preliminary upper material layer 330a may be patterned to form a preliminary upper material pattern 330b.

Referring to FIG. 6C, an ion implantation process 340 using an ion implantation apparatus may be performed to form the preliminary upper material pattern 330b into an upper material pattern 330c. The upper material pattern 330c may include elements doped by the ion implantation process 340.

In an embodiment, a substrate including the base 310, the lower material layer 320 on the base 310, and the preliminary upper material pattern 330b may correspond to the substrate 280 illustrated in FIG. 5.

The ion implantation process 340 may be performed using the ion implantation apparatus described above. For example, the ion implantation apparatus may be the ion implantation apparatus 10 in which the insulating film 109 or 209 is arranged on the inner surface of the source bushing (107, 207), as illustrated in FIG. 1A and FIG. 5. Alternatively, the ion implantation apparatus may be the ion implantation apparatus 10 in which the entire surface of the source bushing 107 is covered by the insulating film 109, as illustrated in FIG. 1B.

Referring to FIG. 6D, a lower material pattern 320a may be formed by etching the lower material layer (320 of FIG. 6C) by an etching process using the upper material pattern 330c as an etching mask. The lower material pattern 320a may be a component of a semiconductor device or a component that may be used to form a semiconductor device. For example, the lower material pattern 320a may be a gate of a transistor. The semiconductor device may be a semiconductor chip.

While the inventive concept has been particularly shown and described with reference to embodiments thereof, it will be understood that various changes in form and details may be made therein without departing from the spirit and scope of the inventive concept.

What is claimed is:

1. An ion implantation apparatus comprising:
a source head including an ion source configured to generate ions;
a source flange fixing a position of the source head;
a source chamber spaced apart from the source head and including a source liner of ground potential;
a source bushing disposed between the source flange and the source chamber; and
a first insulating film covering at least a portion of an inner surface of the source bushing, the first insulating film being adjacent to the ion source, and the first insulating film comprising parylene.

2. The ion implantation apparatus of claim 1, wherein the first insulating film conformally covers the inner surface of the source bushing, the inner surface of the source bushing being curved.

3. The ion implantation apparatus of claim 1, wherein the first insulating film comprises at least one parylene selected from the group consisting of Parylene C, Parylene N, Parylene D, and Parylene HT.

4. The ion implantation apparatus of claim 1, wherein the first insulating film is in contact with the source chamber and the source flange.

5. The ion implantation apparatus of claim 1, wherein each of the source bushing and the first insulating film electrically isolates the source head from the source chamber.

6. The ion implantation apparatus of claim 1, wherein a thickness of the first insulating film is 300 micrometers to 2,000 micrometers.

7. The ion implantation apparatus of claim 1, wherein a dielectric strength of the first insulating film is 5 kV/mil to 20 kV/mil.

8. The ion implantation apparatus of claim 1, wherein a volume resistivity of the first insulating film is 10¹⁶ Ω cm to 10¹⁷ Ω cm.

9. The ion implantation apparatus of claim 1, further comprising a second insulating film arranged on an outer surface of the source bushing,
wherein the second insulating film comprises a same material as the first insulating film.

10. The ion implantation apparatus of claim 9, wherein the second insulating film is in contact with the source chamber and the source flange and is continuously connected to the first insulating film.

11. A semiconductor device manufacturing method, the method comprising:
preparing an ion implantation apparatus including a source head including an ion source configured to generate ions, a source flange fixing a position of the source head, a source chamber spaced apart from the source head, and a source bushing electrically isolating the source head from the source chamber;
forming an insulating film that conformally covers at least a portion of a surface of the source bushing;
forming a preliminary material layer on a base to form a substrate including the base and the preliminary material layer; and
implanting impurity ions into the preliminary material layer with the ion implantation apparatus,
wherein the insulating film comprises parylene and a thickness of the insulating film is 300 micrometers to 2,000 micrometers.

12. The method of claim 11, wherein the forming of the insulating film comprises forming an insulating film using chemical vapor deposition (CVD).

13. The method of claim 11, wherein the forming of the insulating film comprises forming the insulating film on an inner surface of the source bushing.

14. The method of claim 11, wherein the forming of the insulating film comprises forming an insulating film that entirely covers the surface of the source bushing.

15. The method of claim 11, wherein the insulating film comprises at least one parylene selected from the group consisting of Parylene C, Parylene N, Parylene D, and Parylene HT.

16. The method of claim 11, wherein the insulating film is in contact with the source chamber, the source flange, and the source bushing.

17. The method of claim 11, wherein a dielectric strength of the insulating film is 5 kV/mil to 20 kV/mil.

18. The method of claim 11, wherein a volume resistivity of the insulating film is 10¹⁶ Ω cm to 10¹⁷ Ω cm.

19. An ion implantation apparatus comprising:
a source head comprising an ion source configured to generate ions;
a source flange fixing the source head;
a source chamber spaced apart from the source head, surrounding at least a portion of the ion source, and having a ground potential;
a source bushing disposed between the source flange and the source chamber and electrically isolating the source head from the source chamber;
an insulating film covering at least a portion of a surface of the source bushing, the insulating film being adjacent to the ion source, and the insulating film comprising at least one of Parylene C, Parylene N, Parylene D, and Parylene HT;
electrodes configured to attract ions generated from the ion source; and
a mass spectrometer configured to extract at least some ions generated from the ion source, based on a charge-to-mass ratio of ions passing through the electrodes.

20. The ion implantation apparatus of claim 19, wherein the insulating film is in contact with the source flange and the source chamber, and
a thickness of the insulating film is 300 micrometers to 2,000 micrometers.
